(19) United States
(12) Patent Application Publication
(10) Pub. No.: US 2025/0191960 A1
(43) Pub. Date: Jun. 12, 2025

(54) SUBSTRATE PROCESSING APPARATUS

(71) Applicant: Samsung Electronics Co., Ltd., Suwon-si (KR)

(72) Inventors: Hyun Sun CHOI, Suwon-si (KR); Hui Jong CHEONG, Suwon-si (KR); Tae Jong YU, Suwon-si (KR); Sung Hoon LEE, Suwon-si (KR)

(21) Appl. No.: 18/672,107

(22) Filed: May 23, 2024

(30) Foreign Application Priority Data
Dec. 12, 2023 (KR) 10-2023-0179992

(51) Int. Cl. H01L 21/687; H01J 37/32; H01L 21/683

(52) U.S. Cl. CPC H01L 21/68721; H01J 37/32715; H01L 21/6833; H01L 21/68742; H01J 2237/332; H01J 2237/334

(57) ABSTRACT

A substrate processing apparatus is provided. A substrate processing apparatus comprising a body portion, a substrate arrangement portion disposed on the body portion, a bonding portion disposed between the substrate arrangement portion and the body portion, connecting the substrate arrangement portion with the body portion, a first hole installed in the substrate arrangement portion, having a first diameter, a second hole installed in the bonding portion, having a second diameter larger than the first diameter, a first edge band installed in the second hole and installed to be in contact with a lower surface of the substrate arrangement portion, a side surface of the bonding portion, and an upper surface of the body portion and a lifting pin installed to extend through the first hole, the second hole and the first edge band.

### CROSS-REFERENCE TO RELATED APPLICATION

This application claims priority from Korean Patent Application No. 10-2023-0179992 filed on Dec. 12, 2023 in the Korean Intellectual Property Office and all the benefits accruing therefrom under 35 U.S.C. 119, the content of which in its entirety are herein incorporated by reference.

### BACKGROUND

### Technical Field

The present disclosure relates to a substrate processing apparatus.

### Description of the Related Art

Semiconductor devices are widely used in the electronic industry due to their small size, multifunctional and/or low manufacturing cost characteristics. The semiconductor devices are formed using various semiconductor manufacturing processes such as deposition processes, ion implantation processes, photolithography processes and/or etching processes. Some of these semiconductor manufacturing processes may be performed using plasma. In this case, the plasma may mean an ionized gas state of a high temperature, which is made of ions, electrons, radicals and the like.

In a process using plasma, components of a substrate processing apparatus may be consumed by chemically reacting with ions of the plasma. The substrate processing apparatus may include an edge ring mounted in a chamber. The edge ring needs to be periodically replaced for reasons such as wear and contamination.

### BRIEF SUMMARY

An object of the present disclosure is to provide a substrate processing apparatus in which durability is improved.

According to an aspect of the present disclosure, there is provided a substrate processing apparatus comprising a body portion, a substrate arrangement portion disposed on the body portion, a bonding portion disposed between the substrate arrangement portion and the body portion, connecting the substrate arrangement portion with the body portion, a first hole installed in the substrate arrangement portion, having a first diameter, a second hole installed in the bonding portion, having a second diameter larger than the first diameter, a first edge band installed in the second hole and installed to be in contact with a lower surface of the substrate arrangement portion, a side surface of the bonding portion, and an upper surface of the body portion and a lifting pin installed to extend through the first hole, the second hole and the first edge band.

According to another aspect of the present disclosure, there is provided a substrate processing apparatus comprising a body portion including a first body having a first diameter and a second body formed on the first body, having a second diameter smaller than the first diameter, a substrate arrangement portion disposed on the second body of the body portion, having a third diameter larger than the second diameter, a first bonding portion disposed between the substrate arrangement portion and the body portion, connecting the substrate arrangement portion with the body portion, an edge ring disposed to surround the substrate arrangement portion and a first edge band installed in a space defined by the first body, the second body, the substrate arrangement portion and the edge ring and installed to be in contact with a lower surface of the substrate arrangement portion, a side of the first bonding portion, a side of the second first body and an upper surface of the first second body, wherein the first edge band includes a first region, a second region disposed below the first region, being in contact with the first body, a third region disposed above the first region, being in contact with the substrate arrangement portion, and a width of the first region is smaller than a width of the second region or a width of the third region.

According to another aspect of the present disclosure, there is provided a substrate processing apparatus comprising a body portion including a first body having a first diameter and a second body formed on the first body, having a second diameter smaller than the first diameter, a substrate arrangement portion disposed on the second body of the body portion, having a third diameter larger than the second diameter, a bonding portion disposed between the substrate arrangement portion and the body portion, connecting the substrate arrangement portion with the body portion, a first hole installed in the substrate arrangement portion, having a first diameter, a second hole installed in the bonding portion, having a second diameter larger than the first diameter, a third hole installed in the body portion, having a third diameter, a first edge band installed in the second hole and installed to be in contact with a lower surface of the substrate arrangement portion, a side surface of the bonding portion and an upper surface of the body portion, a lifting pin installed to extend through the first hole, the second hole, the third hole and the first edge band, an edge ring disposed on the body portion and disposed to surround the substrate arrangement portion and a second edge band installed in a space defined by the first body, the second body, the substrate arrangement portion and the edge ring and installed to be in contact with a lower surface of the substrate arrangement portion, a side of the bonding portion, a side of the second body and an upper surface of the first body, wherein a surface of the second edge band, which faces the edge ring, has a concave shape.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail some embodiments thereof with reference to the attached drawings, in which:

FIG. 1 is a view illustrating a substrate processing apparatus according to some embodiments of the present disclosure.

FIGS. 2 to 4 are enlarged perspective views illustrating a region X of FIG. 1.

FIGS. 5 to 9 are enlarged cross-sectional views illustrating a region X of FIG. 1.

FIGS. 10 and 11 are enlarged cross-sectional views illustrating a region Y of FIG. 1.

FIGS. 12 to 14 are enlarged views illustrating a method of manufacturing a substrate processing apparatus according to some embodiments of the present disclosure.

FIGS. 15 to 19 are enlarged cross-sectional views illustrating a region Y of FIG. 1.

### DETAILED DESCRIPTION OF THE DISCLOSURE

Hereinafter, embodiments of the present disclosure will be described in detail with reference to the accompanying drawings. The same reference numerals will be used for the same elements on the drawings, and a repeated description of the corresponding elements will be omitted.

Hereinafter, a substrate processing apparatus according to some embodiments of the present disclosure will be described with reference to the accompanying drawings.

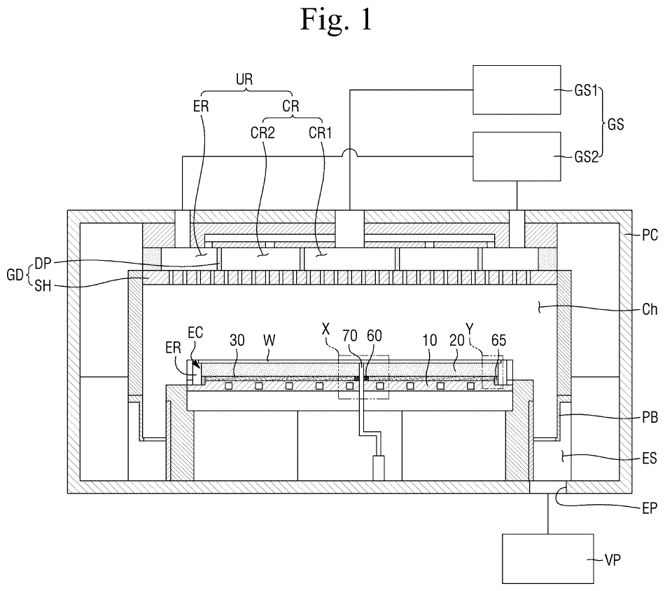

FIG. 1 is a view illustrating a substrate processing apparatus according to some embodiments of the present disclosure.

Referring to FIG. 1, the substrate processing apparatus may be provided. The substrate processing apparatus may refer to an apparatus that processes a substrate by using plasma. The substrate may include a silicon (Si) wafer or the like, but is not limited thereto. The substrate processing apparatus may perform an etching process and/or a deposition process on the substrate by using plasma. For example, the substrate processing apparatus may perform a Bosch process that repeatedly performs an etching process and a deposition process on the substrate by using plasma.

The substrate processing apparatus may generate plasma in various ways. For example, the substrate processing apparatus may generate plasma by using a method such as capacitor coupled plasma (CCP), inductive coupled plasma (ICP) or magnetically enhanced RIE (MERIE), but the present disclosure is not limited thereto. The substrate processing apparatus may generate plasma in another method to perform a process for the substrate. Hereinafter, the substrate processing apparatus will be described based on CCP for convenience.

The substrate processing apparatus may include a process chamber PC, a gas supply unit GS, a gas distribution unit GD, a stage, a plasma baffle PB, a vacuum pump VP and the like.

The process chamber PC may provide a process space Ch. The process chamber PC may be connected to the gas supply unit GS to receive a process gas from the gas supply unit GS. The process chamber PC may be connected to the vacuum pump VP. A fluid such as the process gas in the process space Ch may be discharged toward the vacuum pump VP. The process chamber PC may provide a discharge port EP. The process space Ch may be connected to the vacuum pump VP through the discharge port EP. The discharge port EP may be biased to one side of the process chamber PC. For example, based on FIG. 1, the discharge port EP may be biased to the right of the process chamber PC. The stage, the plasma baffle PB and the like may be disposed in the process chamber PC.

The gas supply unit GS may supply the process gas to the process space Ch. To this end, the gas supply unit GS may include a gas tank, a compressor, a pipe, a controller, and the like. The gas supply unit GS may supply various types of gases. To this end, the gas supply unit GS may include a first gas supply unit GS1 and a second gas supply unit GS2. The first gas supply unit GS1 may supply a first process gas. The first process gas may be supplied to the process space Ch so as to be spread over the entire process space Ch. The second gas supply unit GS2 may supply a second process gas. The second process gas may include a different type of gas which is distinguished from the first process gas. The second process gas may be supplied to be biased to one side of the process space Ch.

The gas distribution unit GD may be positioned in the process chamber PC. The gas distribution unit GD may distribute the process gas to the process space Ch. To this end, the gas distribution unit GD may include a shower head SH and a gas separation plate DP. The shower head SH may provide a plurality of gas supply holes. The shower head SH may also serve as an upper electrode. A distribution space UR and the process space Ch, which are spaces on the shower head SH, may be separated from each other by the shower head SH. The distribution space UR may be divided into a center region CR and an edge region ER. For example, the gas separation plate DP may separate the center region CR from the edge region ER. The center region CR may be divided into a first center region CR1 and a second center region CR2. The first process gas may be supplied to all of the first center region CR1 the second center region CR2 and the edge region ER. The second process gas may be supplied only to the edge region ER. The process gas supplied into the distribution space UR may be distributed through the gas supply holes of the shower head SH, and may move to the process space Ch.

In some embodiments, the stage may be disposed inside the process space Ch to fix a substrate W to an upper surface of an electrostatic chuck EC by using static electricity. The stage may include an electrostatic chuck EC, an edge ring 40, and the like. More detailed description of the stage will be described later.

The plasma baffle PB may surround the stage. For example, the plasma baffle PB may surround the stage below the electrostatic chuck EC, but embodiments of the present disclosure are not limited thereto.

A space below the plasma baffle PB may be referred to as a discharge space ES. The discharge space ES may be connected to the discharge port EP. The plasma baffle PB may send the gas in the process space Ch to the discharge space ES. That is, the gas in the process space Ch may be discharged to the discharge port EP through the discharge space ES by passing through the plasma baffle PB. The plasma may not pass through the plasma baffle PB relatively well. That is, the plasma baffle PB may limit a position of the plasma. The plasma may be concentrated on the substrate disposed on the stage by the plasma baffle PB. Therefore, the plasma baffle PB may be referred to as a confinement ring. The plasma baffle PB may be fixed to the stage and/or the process chamber PC. For example, the plasma baffle PB may be fixed to the process chamber PC by a bolt (not shown) or the like.

The vacuum pump VP may be connected to the process chamber PC. In more detail, the vacuum pump VP may be connected to the process space Ch through the discharge port EP. The vacuum pump VP may suck the fluid in the process space Ch. The vacuum pump VP may be positioned at one side below the process chamber PC, but is not limited thereto. The vacuum pump VP may be positioned next to the process chamber PC.

The electrostatic chuck EC may support the substrate. The electrostatic chuck EC may fix the substrate to a predetermined position by using an electrostatic force. That is, the electrostatic chuck EC may be an electrostatic chuck ESC. To this end, the electrostatic chuck EC may include a body portion 10, a substrate arrangement portion 20, and a first bonding portion 30.

The substrate arrangement portion 20 may support the substrate W. The substrate arrangement portion 20 may include ceramic, but is not limited thereto.

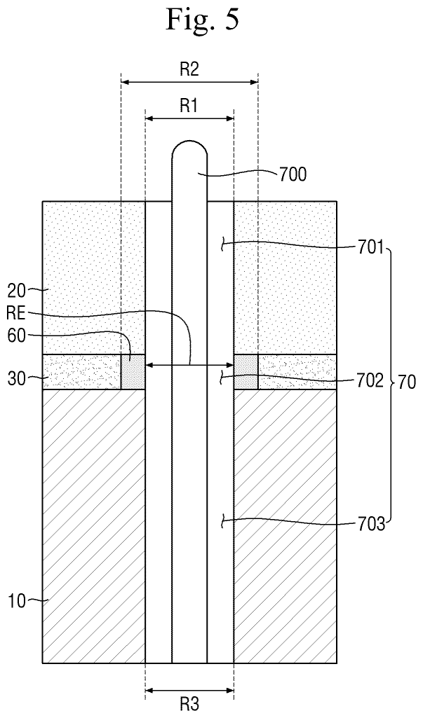

A plurality of lifting holes 70 may be formed in the electrostatic chuck EC so that the plurality of lifting holes 70 passes through the electrostatic chuck EC in a vertical direction. Lifting pins (700 of FIG. 5) may be movably inserted into the lifting holes 70 of the electrostatic chuck EC. The lifting pins 700 may descend in a state that they support the substrate W, and may place the substrate W on a sub-surface of the electrostatic chuck EC. Also, the lifting pins 700 may ascend in a state that they support the substrate W on which a plasma process is completed.

The edge ring 40 may be disposed at an upper edge of the electrostatic chuck EC to surround the substrate W. The edge ring 40 may protect an outer peripheral surface of the substrate W from the plasma. Also, the edge ring 40 may concentrate the plasma on an upper surface of the substrate W.

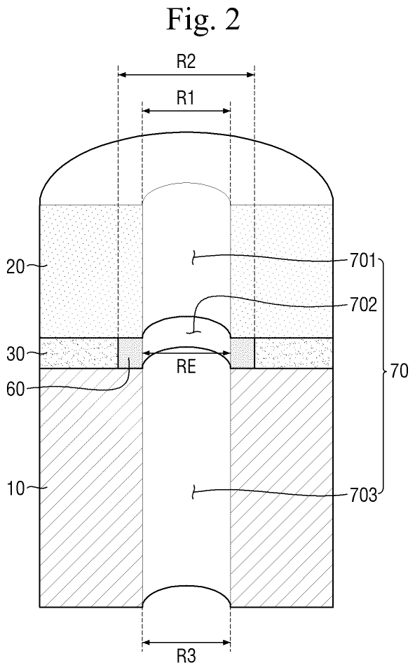

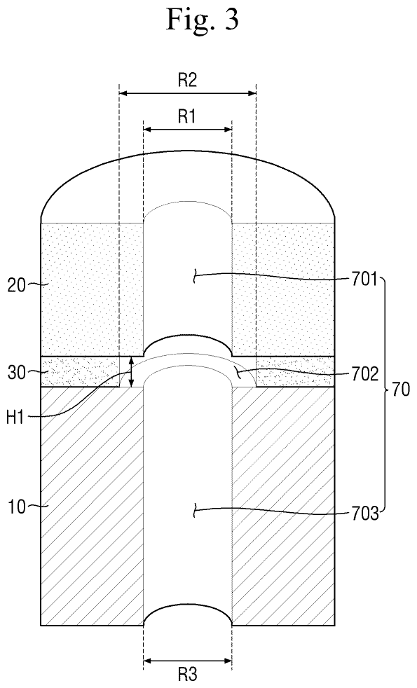

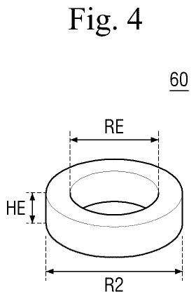

FIGS. 2 to 4 are enlarged perspective views illustrating a region X of FIG. 1.

Referring to FIGS. 2 to 4, in some embodiments, the lifting hole 70 may include a first hole 701, a second hole 702, and a third hole 703. The first hole 701 may be included in the substrate arrangement portion 20. The first hole 701 may have a first diameter R1.

In some embodiments, the second hole 702 may be included in the first bonding portion 30. The second hole 702 may have a second diameter R2. The second diameter R2 may be greater than the first diameter R1. For example, R2 may be greater than R1.

Also, in some embodiments, the second hole 702 may have a first thickness H1. The first thickness H1 may be the same as that of the first bonding portion 30. For example, the second hole 702 may be a cylindrical hole formed by passing through the first bonding portion 30.

The third hole 703 may be included in the body portion 10. The third hole 703 may have a third diameter R3. The third diameter R3 may be smaller than the second diameter R2, and may be the same as the first diameter R1. For example, R3 may be smaller than R2, and may be the same as R1.

In some embodiments, a first edge band 60 may be formed in the second hole 702. The first edge band 60 may be formed to be in contact with a lower surface of the substrate arrangement portion 20, a side surface of the first bonding portion 30, and an upper surface of the body portion 10. For example, a thickness HE of the first edge band 60 may be the same as the first thickness H1. That is, HE may be the same as H1.

Also, a diameter RE of the first edge band 60 may be the same as the first diameter R1 or the third diameter R3. For example, RE may be the same as R1 or R3, and may be smaller than R2.

In some embodiments, the first edge band 60 may include a material having excellent (e.g., high) etch resistance. For example, the first edge band 60 may include sapphire, ketone, alumina and the like.

In the drawing, a cross section of the first edge band 60 is shown in a quadrilateral shape, but is not limited thereto. The cross section of the first edge band 60 may have various shapes.

As the first edge band 60 is included in the second hole 702, the plasma permeated into the lifting hole 70 may be prevented from being in contact with the first bonding portion 30. As a result, the first bonding portion 30 may be prevented from being etched by the plasma. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

FIGS. 5 to 9 are enlarged cross-sectional views illustrating a region X of FIG. 1.

FIG. 5, in contrast to FIG. 2, illustrates a cross-sectional view of region X as opposed to a perspective view. Additionally, FIG. 5 illustrates, in contrast to FIG. 2, the lifting pin 700. Referring to FIG. 5, the electrostatic chuck EC may include the body portion 10, the substrate arrangement portion 20, the first bonding portion 30, the lifting hole 70, the lifting pin 700, and the first edge band 60.

The body portion 10, the first bonding portion 30 and the substrate arrangement portion 20 may be sequentially stacked. For example, the body portion 10 may include aluminum (Al) and the like. The first bonding portion 30 may connect the body portion 10 to the substrate arrangement portion 20. The substrate arrangement portion 20 may fix the substrate W thereon, and may include ceramic and the like.

The substrate arrangement portion 20 may include a first hole 701 having a first diameter R1. In addition, the first bonding portion 30 may include a second hole 702 having a second diameter R2. In some embodiments, the second diameter R2 may be greater than the first diameter R1. For example, R2 may be greater than R1. The body portion 10 may include a third hole 703 having a third diameter R3. In some embodiments, the third diameter R3 may be smaller than the second diameter R2, and may be the same as the first diameter R1. For example, R3 may be smaller than R2, and may be the same as R1.

In some embodiments, the lifting pin 700 may be formed to pass (e.g., extend) through the first hole 701, the second hole 702, and the third hole 703. The lifting pin 700 may move in the vertical direction within the lifting hole 70 to move the substrate W.

In some embodiments, the first edge band 60 may be formed in the second hole 702. The first edge band 60 may be formed to be in contact with the lower surface of the substrate arrangement portion 20, the side surface of the first bonding portion 30 and the upper surface of the body portion 10. The diameter RE of the first edge band 60 may be the same as the first diameter R1 or the third diameter R3. For example, RE may be the same as R1 or R3, and may be smaller than R2. The first edge band 60 may include a material having excellent (e.g., high) etch resistance. For example, the first edge band 60 may include sapphire, ketone, alumina and the like.

In the drawing, a cross section of the first edge band 60 is shown in a quadrilateral shape, but is not limited thereto. The cross section of the first edge band 60 may have various shapes.

As the first edge band 60 is included in the second hole 702, the plasma permeated into the lifting hole 70 may be prevented from being in contact with the first bonding portion 30. As a result, the first bonding portion 30 may be prevented from being etched by the plasma.

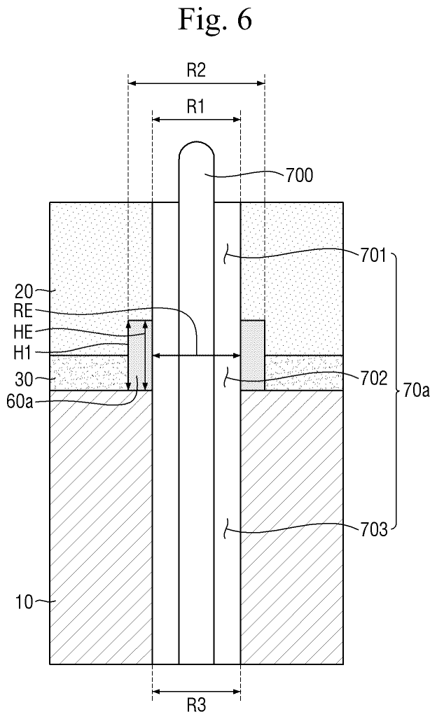

FIGS. 6 to 9 are views corresponding to FIG. 5. For convenience of description, the description will be based on differences from the description made with reference to FIG. 5.

Referring to FIG. 6, in some embodiments, the second hole 702a may have a first thickness H1. The first thickness Hl may be thicker than the first bonding portion 30. For example, the second hole 702a may be a cylindrical hole formed by passing through a portion of the substrate arrangement portion 20 and the first bonding portion 30.

In some embodiments, a first edge band 60a may be formed to be in contact with a lower surface of the substrate arrangement portion 20, a side surface of the substrate arrangement portion 20, a side surface of the first bonding portion 30 and an upper surface of the body portion 10 inside the second hole 702. For example, the thickness HE of the first edge band 60a may be the same as the first thickness H1. That is, HE may be the same as H1.

A fixing force of the first edge band 60a may be improved by increasing the thickness HE of the first edge band 60a. Therefore, the first bonding portion 30 may be prevented from being etched by the plasma.

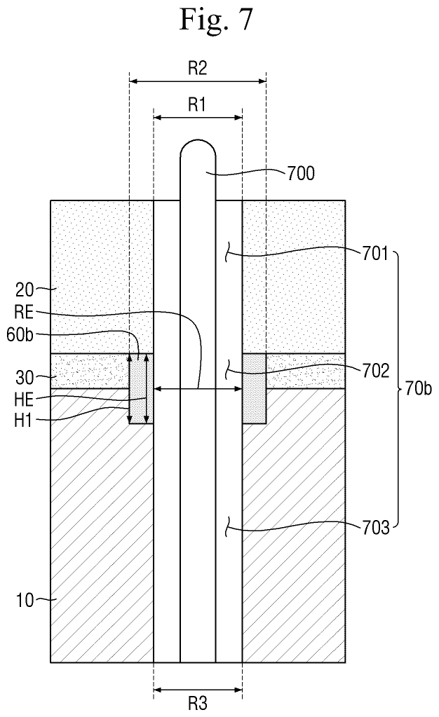

Referring to FIG. 7, in some embodiments, a second hole 702b may have the first thickness H1. The first thickness H1 may be thicker than the first bonding portion 30. For example, the second hole 702b may be a cylindrical hole formed by passing through a portion of the body portion 10 and the first bonding portion 30.

In some embodiments, a first edge band 60b may be formed to be in contact with a lower surface of the substrate arrangement portion 20, a side surface of the first bonding portion 30, a side surface of the first body portion 10 and an upper surface of the body portion 10 inside the second hole 702b. For example, the thickness HE of the first edge band 60b may be the same as the first thickness H1. That is, HE may be the same as H1.

The fixing force of the first edge band 60b may be improved by increasing the thickness HE of the first edge band 60b. Therefore, the first bonding portion 30 may be prevented from being etched by the plasma.

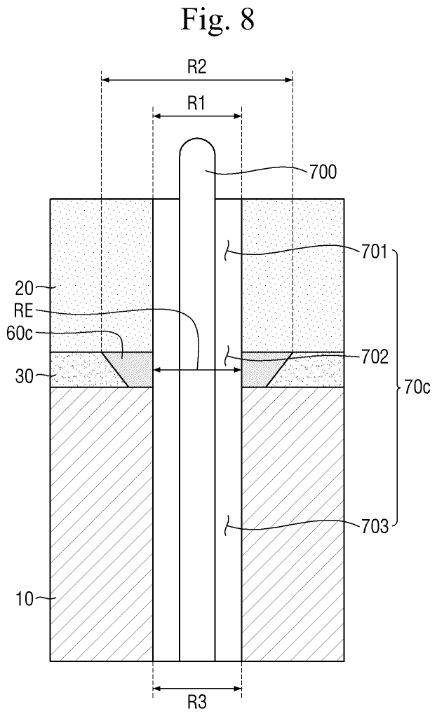

Referring to FIG. 8, in some embodiments, a second hole 702c may be formed such that an inclined surface is produced on a surface of the first bonding portion 30 that faces the lifting pin 700. As the second hole 702c forms the inclined surface on a surface of the first bonding portion 30 that faces the lifting pin 700, a first edge band 60c may be fixed in the second hole 702c to a corner formed by the inclined surface and the lower surface of the substrate arrangement portion 20. Therefore, the fixing force of the first edge band 60c may be improved, and thus durability of the substrate processing apparatus may be improved.

In the drawings, an area in which the first edge band 60c and the substrate arrangement portion 20 are in contact with each other is shown as being larger than an area in which the first edge band 60c and the body portion 10 are in contact with each other, but embodiments of the present disclosure are not limited thereto. For example, an area in which the first edge band 60c and the substrate arrangement portion 20 are in contact with each other may be smaller than an area in which the first edge band 60c and the body portion 10 are in contact with each other.

Also, in the drawings, although a contact surface between the first edge band 60c and the first bonding portion 30 is shown as a smooth surface, embodiments of the present disclosure are not limited thereto. For example, the contact surface between the first edge band 60c and the first bonding portion 30 may include an uneven portion, thereby improving the fixing force of the first edge band 60c.

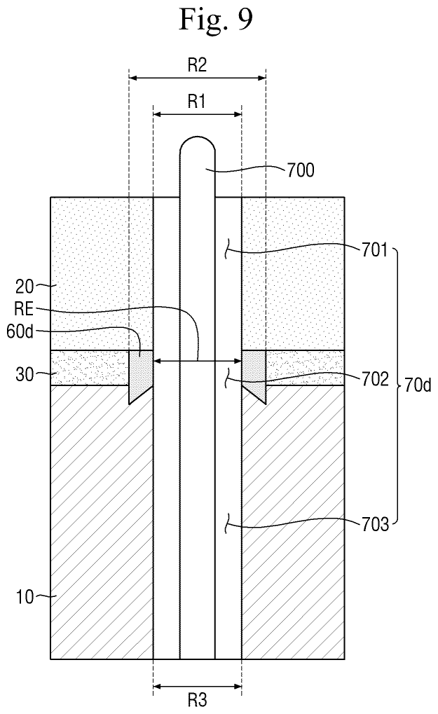

Referring to FIG. 9, in some embodiments, a second hole 702d may be formed such that an inclined surface is produced on a surface of the body portion 10 and a vertical surface is produced that extends along the first bonding portion 30 and the body portion 10. As the second hole 702d forms the inclined surface on a surface of the body portion 10 and a vertical surface (i.e., “pillar surface”) that extends along the first bonding portion 30 and the body portion 10, a first edge band 60d may be fixed in the second hole 702d to a corner formed by the inclined surface and a pillar surface of the first bonding portion 30 and a portion of the body portion 10. Therefore, the fixing force of the first edge band 60d may be improved, and thus durability of the substrate processing apparatus may be improved.

In the drawings, although the inclined surface is shown as a smooth surface, embodiments of the present disclosure are not limited thereto. For example, the inclined surface may include an uneven portion, thereby improving the fixing force of the first edge band 60d.

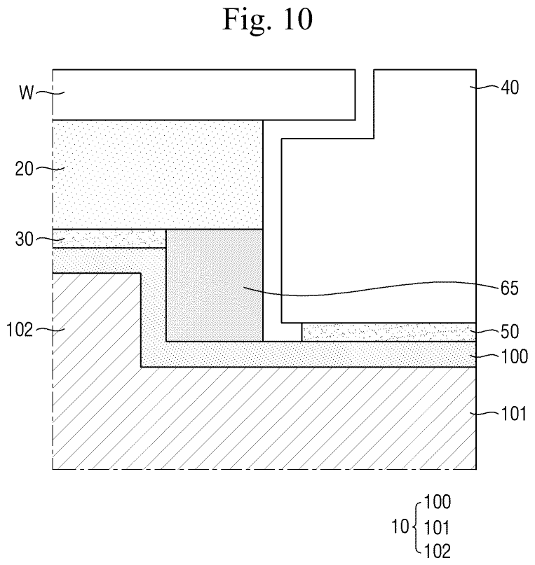

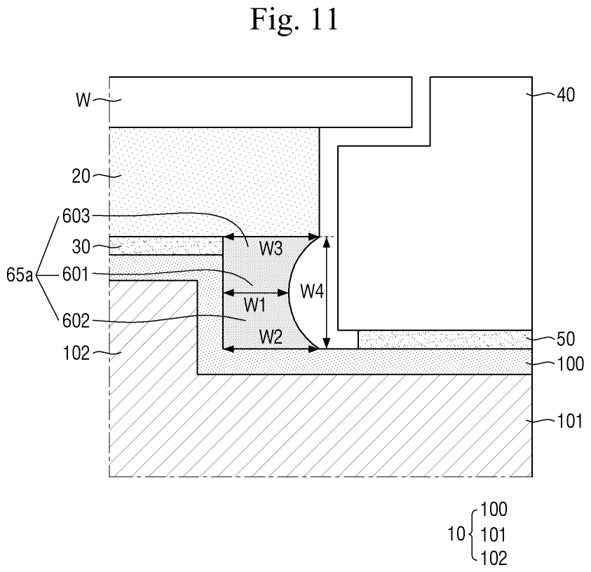

FIGS. 10 and 11 are enlarged cross-sectional views illustrating a region Y of FIG. 1.

Referring to FIG. 10, the substrate processing apparatus may include the body portion 10, the first bonding portion 30, a second bonding portion 50, the substrate arrangement portion 20, the edge ring 40, and a second edge band 65.

In some embodiments, the body portion 10, the first bonding portion 30 and the substrate arrangement portion 20 may be sequentially stacked. For example, the body portion 10 may include aluminum (Al) and the like. The first bonding portion 30 may connect the body portion 10 to the substrate arrangement portion 20.

In some embodiments, the body portion 10 may include a first body 101 and a second body 102. The first body 101 may have a diameter larger than that of the second body 102. For example, the second body 102 may be formed by etching only a portion of the body portion 10.

In some embodiments, the substrate processing apparatus may include an inner space defined by the first body 101, the second body 102, the first bonding portion 30, the substrate arrangement portion 20 and the edge ring 40. As the second body 102 having a diameter smaller than that of the first body 101 is formed, a thickness of the inner space may be greater than that of the first bonding portion 30.

In some embodiments, the second edge band 65 may be installed in the inner space. The second edge band 65 may include a material having elasticity. The second edge band 65 may be in contact with a lower surface of the substrate arrangement portion 20, a side surface of the first bonding portion 30, a side surface of the second body 102 and an upper surface of the first body 101 inside the inner space, and may not be in contact with the edge ring 40. In addition, the second edge band 65 may be installed to surround the pillar surface of the first bonding portion 30 and the second body 102. Therefore, the second edge band 65 may generate tension in a central direction of the first bonding portion 30 and the body portion 10.

Also, in some embodiments, the second edge band 65 (and the different embodiments described herein) may further include a material having high thermal conductivity, such as perfluoro rubber. The second edge band 65 may further include, for example, a material containing carbon (C) and/or silicon (Si) in the form of a filler may be injected into the second edge band 65. As one example, the second edge band 65 may include perfluoro rubber that includes carbon and/or silicon. Therefore, heat may be well transferred from a refrigerant connected to the body portion 10 to the substrate W disposed on the substrate arrangement portion 20.

In the drawings, although a surface of the second edge band 65, which faces the edge ring 40, is shown in a flat shape, embodiments of the present disclosure are not limited thereto. For example, the surface of the second edge band 65, which faces the edge ring 40, may have a concave shape or a convex shape. Another form of the second edge band 65 will be described below.

In some embodiments, a portion of the body portion 10 is etched such that the inner space between the substrate arrangement portion 20 and the body portion 10 may be enlarged. As the inner space is enlarged, a thickness of the second edge band 65 installed in the inner space may be also increased. As the thickness of the second edge band 65 is increased, a fixing force of the second edge band 65 may be improved. As a result, the first bonding portion 30 may be prevented from being etched by the plasma, whereby durability of the substrate processing apparatus may be improved.

In some embodiments, the body portion 10 may further include a coating layer 100 on a surface thereof. The coating layer 100 may include an insulating material. For example, the coating layer 100 may include aluminum oxide (Al₂O₃) or yttrium oxide (Y₂O₃).

In some embodiments, the substrate arrangement portion 20 may be formed on the second body 102. The substrate arrangement portion 20 and the second body 102 may be connected to each other by the first bonding portion 30. The substrate arrangement portion 20 may fix the substrate W on an upper surface thereof. The substrate arrangement portion 20 may include ceramic and the like. For example, the first bonding portion 30 may include epoxy, but embodiments of the present disclosure are not limited thereto.

In some embodiments, the body portion 10, the second bonding portion 50 and the edge ring 40 may be sequentially stacked. The second bonding portion 50 may connect the body portion 10 with the edge ring 40. The edge ring 40 may be spaced apart from the substrate W and the side surface of the substrate arrangement portion 20 to surround the substrate W and the side surface of the substrate arrangement portion 20.

Referring to FIG. 11, in some embodiments, a second edge band 65a including a first region 601, a second region 602, and a third region 603 may be provide. The second region 602 may be disposed below the first region 601. The third region 603 may be disposed above the first region 601.

The first region 601 of the second edge band 65a may have a first width W1. The second region 602 of the second edge band 65a may have a second width W2. The third region 603 of the second edge band 65a may have a third width W3. The first width W1 may be smaller than the second width W2, and may be smaller than the third width W3. For example, the surface of the second edge band 65a, which faces the edge ring 40, may have a concave shape. Also, for example, the second width W2 and the third width W3 of the second edge band 65a may be symmetrical with respect to the first region 601, but embodiments of the present disclosure are not limited thereto.

As the second width W2 and the third width W3 are increased to be greater than the first width W1, tension between the substrate arrangement portion 20 and the body portion 10 in the vertical direction may be more increased than the case that the first width W1 to the third width W3 are all the same. Therefore, the fixing force of the second edge band 65a between the substrate arrangement portion 20 and the body portion 10, which have their respective thermal expansion coefficients different from each other, may be enhanced, and durability of the substrate processing apparatus may be improved.

Also, in some embodiments, a ratio between a fourth width W4 (measured in a distance perpendicular to the measured distance of the first width W1, the second width W2, and the third width W3) and the first width W1 may be adjusted, so that tension between the substrate arrangement portion 20 and the body portion 10 in the vertical direction may be increased. Therefore, the fixing force of the second edge band 65a between the substrate arrangement portion 20 and the body portion 10, which have their thermal expansion coefficients different from each other, may be enhanced, and durability of the substrate processing apparatus may be improved.

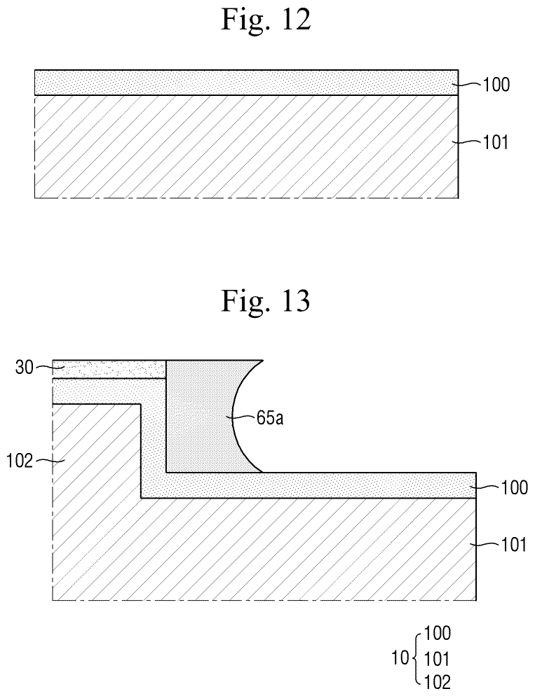

FIGS. 12 to 14 are enlarged views illustrating a method of manufacturing a substrate processing apparatus according to some embodiments of the present disclosure.

Referring to FIGS. 12 and 13, a first body 101 and a coating layer 100 stacked on the first body 101 may be provided as a stacked structure. A portion of the stacked structure is etched, so that the first body 101 and the second body 102, which have their respective diameters different from each other, are formed. Afterwards, the second edge band 65a is formed on a side surface of the coating layer 100 and a top surface of the coating layer 100 so as to contact the side surface of the coating layer 100 and the top surface of the coating layer 100. Although the surface of the second edge band 65a, which faces the edge ring 40, is shown in a concave shape, embodiments of the present disclosure are not limited thereto. For example, the surface of the second edge band 65a, which faces the edge ring 40, may be a flat shape or a convex shape. Additionally, although a coating layer 100 is illustrated, in certain embodiments, the coating layer 100 may be omitted. For example, the first body 101 may be provided and etched so that the first body 101 and the second body 102, which have their respective diameters different from each other, are formed. Afterwards, the second edge band 65a is formed on a side surface of the second body 102 and a top surface of the first body 101 so as to contact the side surface of the second body 102 and the top surface of the first body 101.

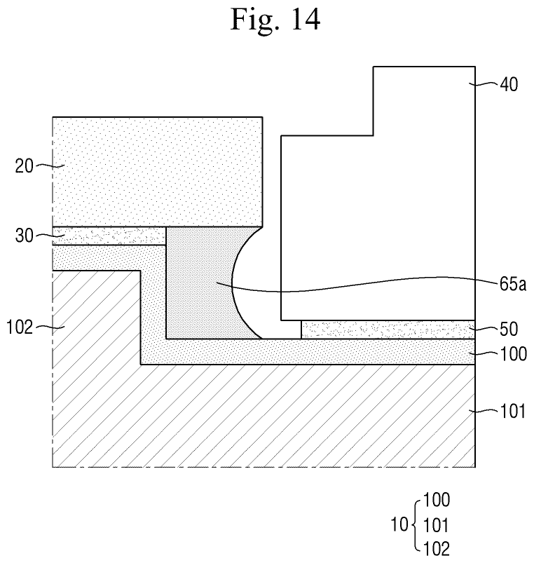

The first bonding portion 30 may be formed above the second body 102 so as to contact a top surface of the coating layer 100. In embodiments in which the coating layer 100 is omitted, the first bonding portion 30 may be formed above the second body 102 so as to contact a top surface of the second body 102. Moreover, although the formation of the second edge band 65a is illustrated in FIGS. 13 and 14, any of the second edge bands disclosed herein may be provided instead of the second edge band 65a.

Referring to FIG. 14, the substrate arrangement portion 20 is disposed on the upper surface of the first bonding portion 30. The second bonding portion 50, spaced apart from the second edge band 65a, is disposed on the upper surface of the first body 101. Also, the edge ring 40 may be disposed on an upper surface of the second bonding portion 50.

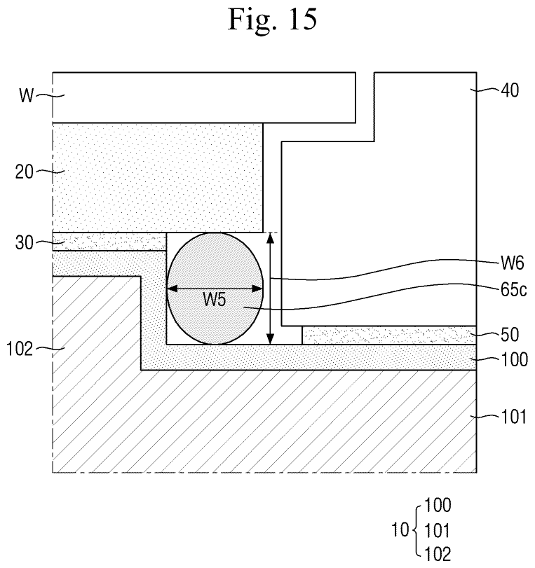

FIGS. 15 to 19 are enlarged cross-sectional views illustrating a region Y of FIG. 1. FIGS. 15 to 19 are views corresponding to FIGS. 10 and 11. For convenience of description, the following description will be based on differences from the description made with reference to FIGS. 10 and 11. Also, although FIGS. 15 to 19 illustrate the inclusion of the coating layer 100, the coating layer may be omitted from the embodiments disclosed in FIGS. 15 to 19 as described above with respect to FIGS. 13 and 14. For the brevity of discussion, the description provided below in relation to FIGS. 15 to 19 are provided based on the omission of the coating layer 100.

Referring to FIG. 15, in some embodiments, a second edge band 65c having an elliptical shape may be provided. For example, a horizontal width of the second edge band 65c may have a fifth width W5. A vertical width of the second edge band 65c may have a sixth width W6.

In some embodiments, the fifth width W5 may be smaller than the sixth width W6. For example, the second edge band 65c may have an elliptical shape having a longer diameter in the vertical direction, but embodiments of the present disclosure are not limited thereto.

As the sixth width W6 is to be greater than the fifth width W5, tension between the substrate arrangement portion 20 and the body portion 10 in the vertical direction may be more increased than the case that the fifth width W5 and the sixth width W6 are the same as each other. Therefore, the fixing force of the second edge band 65c between the substrate arrangement portion 20 and the body portion 10, which have their respective thermal expansion coefficients different from each other, may be enhanced, and durability of the substrate processing apparatus may be improved.

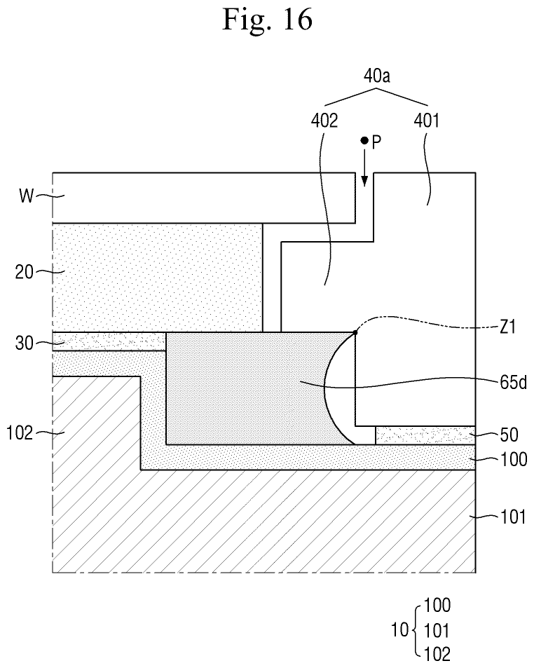

Referring to FIG. 16, the substrate processing apparatus may include a body portion 10, a first bonding portion 30, a second bonding portion 50, a substrate arrangement portion 20, an edge ring 40a, and a second edge band 65d.

In some embodiments, the edge ring 40a may include a first edge ring 401 and a second edge ring 402. The second edge ring 402 may be protruded from the first edge ring 401.

In some embodiments, the second edge band 65d may be installed in the inner space defined by the first body 101, the second body 102, the first bonding portion 30, the substrate arrangement portion 20 and the edge ring 40a. In addition, the second edge band 65d may be in contact with the lower surface of the second edge ring 402, the lower surface of the substrate arrangement portion 20, the side surface of the first bonding portion 30, the side surface of the second body 102 and the upper surface of the first body 101 inside the inner space, and may not be in contact with a side surface of the first edge ring 401. Durability of the substrate processing apparatus may be improved by the second edge ring 402. In detail, the amount of plasma P permeated into the inner space may be reduced depending on complexity of a path from the space on the substrate W to the inner space.

For example, as compared with the edge ring 40 that does not include a protrusion, the substrate processing apparatus including the second edge ring 402 further includes a first edge Z1 in the path of the plasma P. Therefore, the amount of the plasma P permeated into the inner space may be reduced, and durability of the substrate processing apparatus is improved.

In the drawing, although the surface of the second edge band 65d, which faces the edge ring 40a, is shown in a concave shape, embodiments of the present disclosure are not limited thereto. For example, the surface of the second edge band 65d, which faces the edge ring 40a, may have a flat shape or a convex shape.

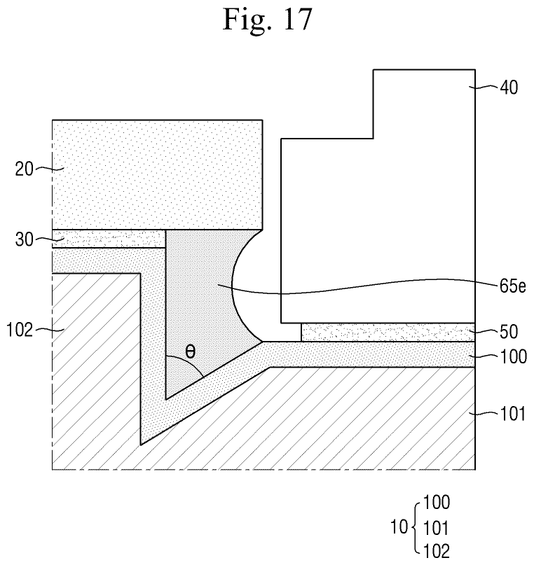

Referring to FIG. 17, the substrate processing apparatus may include a body portion 10, a first bonding portion 30, a second bonding portion 50, a substrate arrangement portion 20, an edge ring 40, and a second edge band 65c.

In some embodiments, the first body 101 may include an inclined surface on an upper surface thereof. An angle formed by the inclined surface and the side surface of the second body 102 may be θ. For example, θ may be an acute angle.

In some embodiments, the second edge band 65e may be installed in the inner space defined by the first body 101, the second body 102, the first bonding portion 30, the substrate arrangement portion 20 and the edge ring 40. In addition, the second edge band 65e may be in contact with the inclined surface of the first body 101, the side surface of the second body 102, the side surface of the first bonding portion 30 and the lower surface of the substrate arrangement portion 20 inside the inner space, and may not be in contact with a side surface of the edge ring 40. As the inclined surface is included on the first body 101, the fixing force of the second edge band 65e may be enhanced. Therefore, durability of the substrate processing apparatus may be improved.

In the drawing, although the surface of the second edge band 65e, which faces the edge ring 40, is shown in a concave shape, embodiments of the present disclosure are not limited thereto. For example, the surface of the second edge band 65e, which faces the edge ring 40, may have a flat shape or a convex shape.

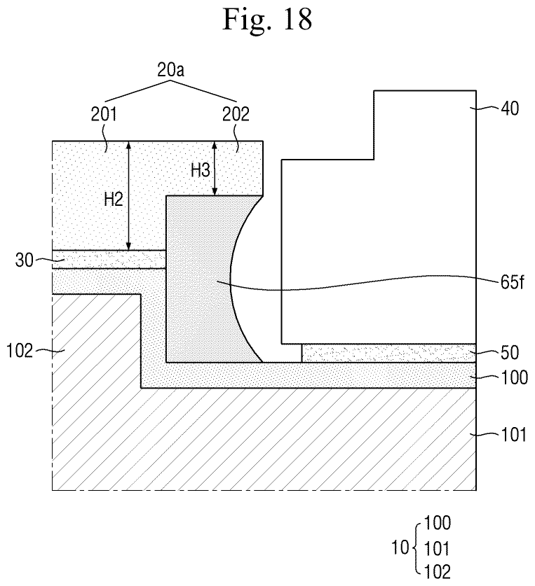

Referring to FIG. 18, the substrate processing apparatus may include a body portion 10, a first bonding portion 30, a second bonding portion 50, a substrate arrangement portion 20a, an edge ring 40, and a second edge band 65f.

In some embodiments, the substrate arrangement portion 20a may include a first substrate arrangement portion 201 and a second substrate arrangement portion 202. The first substrate arrangement portion 201 may have a second height H2. The second substrate arrangement portion 202 may have a third height H3. For example, H2 may be greater than H3.

In some embodiments, the second edge band 65f may be installed in the inner space defined by the first body 101, the second body 102, the first bonding portion 30, the substrate arrangement portion 20a and the edge ring 40. In addition, the second edge band 65f may be in contact with the upper surface of the first body 101, the side surface of the second body 102, the side surface of the first bonding portion 30, the side surface of the first substrate arrangement portion 201 and the lower surface of the second substrate arrangement portion 202 inside the inner space, and may not be in contact with the side surface of the edge ring 40. As the substrate arrangement portion 20 is etched, the thickness of the second edge band 65f may be increased. Therefore, the fixing force of the second edge band 65f may be enhanced, and durability of the substrate processing apparatus may be improved.

In the drawing, the surface of the second edge band 65f, which faces the edge ring 40, is shown in a concave shape, but embodiments of the present disclosure are not limited thereto. For example, the surface of the second edge band 65f, which faces the edge ring 40, may have a flat shape or a convex shape.

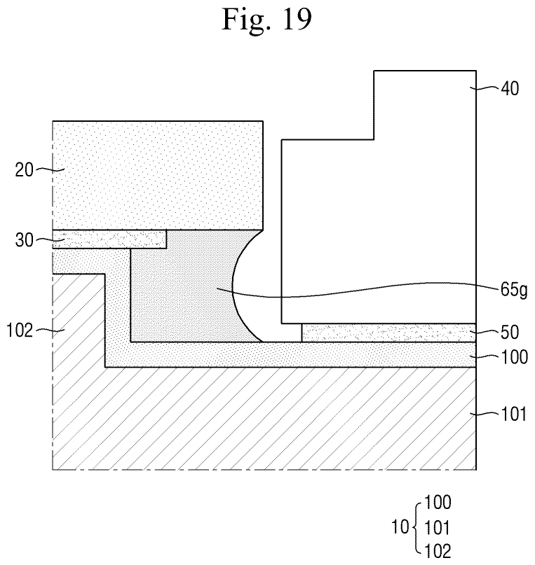

Referring to FIG. 19, the substrate processing apparatus may include a body portion 10, a first bonding portion 30, a second bonding portion 50, a substrate arrangement portion 20, an edge ring 40, and a second edge band 65g.

In some embodiments, the first bonding portion 30 may be more protruded in a direction of the edge ring 40 than the second body 102. In some embodiments, the second edge band 65g may be installed in the inner space defined by the first body 101, the second body 102, the first bonding portion 30, the substrate arrangement portion 20 and the edge ring 40. In addition, the second edge band 65g may be in contact with the upper surface of the first body 101, the side surface of the second body 102, a lower surface of the first bonding portion, the side surface of the first bonding portion 30, and the lower surface of the second substrate arrangement portion 20 inside the inner space, and may not be in contact with the side surface of the edge ring 40. The second edge band 65g may be in contact with the lower surface of the substrate arrangement portion 20, the side surface and the lower surface of the first bonding portion 30, the side surface of the second body 102 and the upper surface of the first body 101 inside the space, and may not be in contact with the edge ring 40.

Also, in some embodiments, the second edge band 65g may further include a material having high thermal conductivity. For example, a material containing carbon (C) or silicon (Si) in the form of a filler may be injected into the second edge band 65g. Therefore, heat may be well transferred from the refrigerant connected to the body portion 10 to the substrate W disposed on the substrate arrangement portion 20.

Therefore, as the area of the first bonding portion 30 having high thermal conductivity is maximized and the body portion 10 is etched instead, both thermal conductivity and the fixing force of the second edge band 65g may be increased.

In the drawing, although the surface of the second edge band 6g5, which faces the edge ring 40, is shown in a concave shape, embodiments of the present disclosure are not limited thereto. For example, the surface of the second edge band 65g, which faces the edge ring 40, may have a flat shape or a convex shape.

Although embodiments of the present disclosure have been described with reference to the accompanying drawings, it will be apparent to those skilled in the art that the present disclosure can be manufactured in various forms without being limited to the above-described embodiments and can be embodied in other specific forms without departing from technical spirits and essential characteristics of the present disclosure. Thus, the above embodiments are to be considered in all respects as illustrative and not restrictive.

What is claimed is:

1. A substrate processing apparatus comprising:
a body portion;
a substrate arrangement portion disposed on the body portion;
a bonding portion disposed between the substrate arrangement portion and the body portion, connecting the substrate arrangement portion with the body portion;
a first hole installed in the substrate arrangement portion, having a first diameter;
a second hole installed in the bonding portion, having a second diameter larger than the first diameter;
a first edge band installed in the second hole and installed to be in contact with a lower surface of the substrate arrangement portion, a side surface of the bonding portion, and an upper surface of the body portion; and
a lifting pin installed to extend through the first hole, the second hole and the first edge band.

2. The substrate processing apparatus of claim 1, further comprising a third hole installed in the body portion, having a third diameter,
wherein the lifting pin extends through the third hole.

3. The substrate processing apparatus of claim 2, wherein the first diameter is the same as the third diameter.

4. The substrate processing apparatus of claim 3, wherein a diameter of the first edge band is the same as the first diameter.

5. The substrate processing apparatus of claim 1, wherein the second hole has a first thickness, and the first thickness is thicker than the bonding portion.

6. The substrate processing apparatus of claim 5, wherein the second hole is installed in a portion of the substrate arrangement portion and the bonding portion, and a thickness of the first edge band is the same as the first thickness.

7. The substrate processing apparatus of claim 5, wherein the second hole is installed in the bonding portion and a portion of the body portion, and a thickness of the first edge band is the same as the first thickness.

8. The substrate processing apparatus of claim 1, wherein the side surface of the bonding portion in contact with the first edge band includes an inclined surface.

9. The substrate processing apparatus of claim 1, wherein the upper surface of the body portion in contact with the first edge band includes an inclined surface.

10. A substrate processing apparatus comprising:
a body portion including a first body having a first diameter and a second body formed on the first body, having a second diameter smaller than the first diameter;
a substrate arrangement portion disposed on the second body of the body portion, having a third diameter larger than the second diameter;
a first bonding portion disposed between the substrate arrangement portion and the body portion, connecting the substrate arrangement portion with the body portion;
an edge ring disposed to surround the substrate arrangement portion; and
a first edge band installed in a space defined by the first body, the second body, the substrate arrangement portion and the edge ring and installed to be in contact with a lower surface of the substrate arrangement portion, a side of the first bonding portion, a side of the second body and an upper surface of the first body,
wherein the first edge band includes:
a first region;
a second region disposed below the first region, being in contact with the first body;
a third region disposed above the first region, being in contact with the substrate arrangement portion, and
a width of the first region is smaller than a width of the second region or a width of the third region.

11. The substrate processing apparatus of claim 10, wherein a surface of the first edge band, which faces the edge ring, has a concave shape.

12. The substrate processing apparatus of claim 10, wherein the first edge band includes perfluoro rubber, and further includes carbon or silicon.

13. The substrate processing apparatus of claim 10, wherein the first edge band is not in contact with the edge ring.

14. The substrate processing apparatus of claim 10, further comprising a second bonding portion disposed between the first body and the edge ring, and for fixing the edge ring to the first body,
wherein the first edge band directly faces the second bonding portion, and the first edge band is not in contact with the second bonding portion.

15. The substrate processing apparatus of claim 10, wherein a surface of the edge ring, which faces the substrate arrangement portion, further includes a protrusion, and an upper surface of the first edge band is in contact with a lower surface of the protrusion.

16. The substrate processing apparatus of claim 10, wherein an upper surface of the first body includes an inclined surface, and an angle formed by a side surface of the second body and the inclined surface is an acute angle.

17. The substrate processing apparatus of claim 10, wherein the substrate arrangement portion includes a first substrate arrangement portion having a first thickness and a second substrate arrangement portion having a second thickness smaller than the first thickness, and
the first edge band is in contact with a lower surface of the second region.

18. The substrate processing apparatus of claim 10, wherein the first bonding portion is more protruded in a direction of the edge ring than the second body.

19. A substrate processing apparatus comprising:
a body portion including a first body having a first diameter and a second body formed on the first body, having a second diameter smaller than the first diameter;
a substrate arrangement portion disposed on the second body of the body portion, having a third diameter larger than the second diameter;
a bonding portion disposed between the substrate arrangement portion and the body portion, connecting the substrate arrangement portion with the body portion;
a first hole installed in the substrate arrangement portion, having a first diameter;
a second hole installed in the bonding portion, having a second diameter larger than the first diameter;
a third hole installed in the body portion, having a third diameter;
a first edge band installed in the second hole and installed to be in contact with a lower surface of the substrate arrangement portion, a side surface of the bonding portion and an upper surface of the body portion;
a lifting pin installed to extend through the first hole, the second hole, the third hole and the first edge band;
an edge ring disposed on the body portion and disposed to surround the substrate arrangement portion; and
a second edge band installed in a space defined by the first body, the second body, the substrate arrangement portion and the edge ring and installed to be in contact with a lower surface of the substrate arrangement portion, a side of the bonding portion, a side of the second body and an upper surface of the first body,
wherein a surface of the second edge band, which faces the edge ring, has a concave shape.

20. The substrate processing apparatus of claim 19, wherein the second edge band includes perfluoro rubber, and further includes carbon or silicon.
